(19) United States
(12) Patent Application Publication
(10) Pub. No.: US 2003/0159941 A1
(43) Pub. Date: Aug. 28, 2003

(54) Additives for electroplating solution

(75) Inventors: Rajeev Bajaj, Fremont, CA (US); Girish Dixit, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/074,141

(22) Filed: Feb. 11, 2002

(51) Int. Cl. B05B 1/00; C23C 16/00; C23C 20/00; C09D 5/10; C09D 5/00; C25D 3/38

(52) U.S. Cl. 205/296; 106/1.26; 427/437

(57) ABSTRACT

Embodiments of the invention generally provide a method and plating solution for reducing the degradation of additives in electroplating solutions. The method generally includes adding an anti-oxidant to the electroplating solution in an amount effective to reduce the degradation of additives in the plating solution. The plating solution generally includes copper ions, at least one organic plating additive, and at least one anti-oxidant in an amount sufficient to reduce the degradation of the organic plating additives in the plating solution.

### BACKGROUND OF THE INVENTION

1. Field of the Invention

Embodiments of the present invention generally relate to a method and a plating solution for reducing additive degradation in electroplating solutions.

2. Description of the Related Art

Electroplating processes for manufacturing semiconductor devices typically require a thin, continuous, electrically conductive seed layer to be deposited on the substrate prior to the plating process. The seed layer generally is formed of a conductive metal, such as copper, and is conventionally deposited on the substrate using PVD or CVD techniques. Electroplating a desired metal is then generally accomplished by applying an electrical bias to the seed layer and exposing the substrate to an electroplating solution containing metal ions that will plate over the seed layer in the presence of the electrical bias.

Copper has a lower resistivity, e.g., 1.7 μΩ-cm compared to 3.1 μΩ-cm for aluminum, and can carry a higher current density than aluminum. Therefore, it is desirable to use copper to form interconnects in semiconductor devices, rather than aluminum. Conventional copper electroplating solutions typically consist of copper sulfate, sulfuric acid, and multiple additives to aid in depositing copper on the surface of a substrate and in filling sub-micron sized features, e.g., vias and interconnects. The additives may include any combination of, but not limited to, levelers, brighteners, inhibitors, suppressors, enhancers, accelerators, and surfactants. The additives are typically organic molecules that adsorb onto the surface of the substrate, thereby affecting the local plating rate on the substrate. Certain additives may decrease the ionization rate of metal atoms, thereby inhibiting the deposition process, whereas other additives may increase the deposition rate of metal ions.

However, a problem encountered in utilizing conventional electroplating processes is that organic additives degrade over time as a result of electrical current, light, air and chemical interactions. The degradation of organic additives generally increases as the plating current increases. As such, conventional processes typically overcome additive degradation by adding fresh additives to the electroplating solution. The amount and timing of the fresh additive addition is dependent on costly chemical analysis to continuously measure the concentration of additives in the electroplating solution. Chemical analysis systems generally include many sensors for monitoring plating conditions within the solution. The sensors typically detect additive degradation, thereby indicating the additional amount of additive to be added to the solution. Although chemical analysis is necessary to monitor traditional electroplating solutions, the analysis is not always accurate by the time the results are available because the additives are continuously degrading.

In addition, although the fresh additive restores the additive concentration in the electroplating solution, a substantial portion of the degraded additives remain in the solution, thereby building up, and potentially reducing plating performance. Although the effect of organic buildup on plating performance is unknown, it is believed that the initial organic additive compositions are altered by chemical interactions. Therefore, it is desirable to limit degraded organic additive buildup in the plating solution. As a result, traditional systems remove a portion of the electroplating solution based on time and plating usage, e.g., up to 25 percent of the solution volume per day. Additional electroplating solution is then added to restore the solution volume.

Therefore, there exists a need for a method and plating solution for reducing additive degradation in electroplating solutions.

### SUMMARY OF THE INVENTION

Embodiments of the present invention generally relate to a method for reducing the degradation of additives in a plating solution. The method generally includes adding an anti-oxidant to a plating solution in an amount effective to reduce the degradation of additives in the plating solution.

Embodiments of the invention further relate to a method for plating metal on a substrate. The method generally includes disposing the substrate and an anode in a plating solution, the plating solution having metal ions, one or more organic additives configured to enhance one or more plating characteristics, and at least one anti-oxidant in an amount effective to reduce degradation of the one or more organic additives. The method further includes plating metal ions from the plating solution onto the substrate.

Embodiments of the invention further relate to a method for reducing degraded organic plating additives in an electrochemical plating solution. The method generally includes adding sodium stannate to the electrochemical plating solution, the sodium stannate being added in an amount corresponding to a time varying amount of degraded organic plating additives generated in the electrochemical plating solution.

Embodiments of the invention further relate to a method for plating copper in an electrochemical plating system. The method generally includes contacting a substrate having an electrical bias applied thereto with a plating solution, wherein the plating solution has a copper source, at least one organic additive, and at least one anti-oxidant selected from the group consisting of sodium stannate, hydroquinone, butylated hydroxy toluene, and combinations thereof.

Embodiments of the invention additionally relate to a plating solution for an electrochemical plating system. The plating solution generally is a liquid solution containing copper ions to be plated on a substrate, at least one organic plating additive configured to facilitate a plating characteristic of the copper ions onto a substrate, and at least one anti-oxidant in an amount sufficient to reduce the degradation for the at least one organic plating additive in the plating solution.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof, which are illustrated in the appended drawings. It is to be noted, however, that the appended drawings illustrate only typical embodiments of this invention, and therefore, are not to be considered limiting of its scope, for the invention may admit to other equally effective embodiments.

FIG. 1 is a perspective view of an exemplary electroplating system of the invention.

FIG. 2 is an illustration of the organic additive degradation in conventional electroplating solutions.

### DETAILED DESCRIPTION OF THE PREFERRED EMBODIMENT

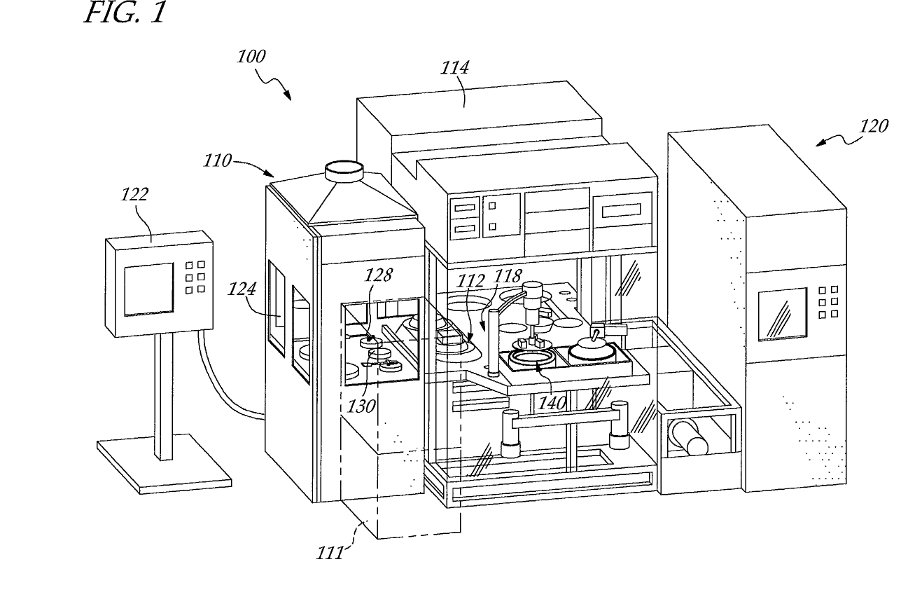

FIG. 1 is a perspective view of an electroplating system 100 including a mainframe 114, an electroplating solution replenishing system 120, and a control system 122. The mainframe generally includes a thermal anneal chamber 111, a loading station 110, a spin rinse dry station 112, and a plurality of processing stations 118. The loading station 110 generally includes one or more substrate cassette receiving areas 124, generally known as pod loaders, one or more loading station transfer robots 128, and at least one substrate orientor 130. Each processing station 118 includes one or more processing cells 140.

The control system 122, may be a programmable microprocessor configured to interface with the various components of the system 100 and provide controlling signals thereto. The electroplating solution replenishing system 120 is positioned adjacent to the electroplating system 100 in fluid communication with the process cells 140 in order to circulate electroplating solution to the cells 140.

Embodiments of the invention generally employ copper plating solutions having copper sulfate at a concentration between about 5 g/L and about 100 g/L, an acid at a concentration between about 5 g/L and about 200 g/L, and halide ions, such as chloride, at a concentration between about 10 ppm and about 200 ppm. The acid may include sulfuric acid, phosphoric acid, and/or derivatives thereof. In addition to copper sulfate, the electroplating solution may include other copper salts, such as copper fluoborate, copper gluconate, copper sulfamate, copper sulfonate, copper pyrophosphate, copper chloride, or copper cyanide.

The electroplating solution may further include one or more additives. Additives, which may be, for example, levelers, inhibitors, suppressors, brighteners, accelerators, or other additives known in the art, are typically organic materials that adsorb onto the surface of the substrate being plated. Useful suppressors typically include polyethers, such as polyethylene, glycol, or other polymers, such as polypropylene oxides, which adsorb on the substrate surface, slowing down copper deposition in the adsorbed areas. Useful accelerators typically include sulfides or disulfides, such as bis(3-sulfopropyl) disulfide, which compete with suppressors for adsorption sites, accelerating copper deposition in adsorbed areas. Useful inhibitors typically include sodium benzoate and sodium sulfite, which inhibit the rate of copper deposition on the substrate. During plating, the additives are consumed at the substrate surface, but are being constantly replenished by the electroplating solution. However, differences in diffusion rates of the various additives result in different surface concentrations at the top and the bottom of the features, thereby setting up different plating rates in the features. Ideally, these plating rates should be higher at the bottom of the feature for bottom-up fill. Thus, an appropriate composition of additives in the plating solution is required to achieve a void-free fill of the features.

Although electrochemical deposition of copper can be achieved by pulse plating using two component chemistries, i.e., electroplating solutions including accelerators and suppressors, pulse plating on a non-continuous seed layer leads to erosion of the seed layer at regions of minimal seed layer coverage. As a result, most electroplating systems use three component chemistries, i.e., suppressors, accelerators, and levelers in an electroplating solution.

Although the cause of organic additive degradation is unknown, it is believed that the turbulent flow of electroplating solution adjacent an anode in the plating cell increases the rate of organic additive degradation. While not wishing to be bound by theory, the present invention contemplates that the addition of an external energy source to the electroplating solution, e.g., light, heat, or electrical current, operates to displace an electron from molecules in the solution, thereby creating charged free radicals. The free radicals then alter organic additives in the electroplating solution by either combining with organic additives to absorb an electron or by breaking bonds within organic additives to absorb electrons. Therefore, embodiments of the present invention include electroplating solutions having anti-oxidants therein. It is believed that anti-oxidants reduce the degradation of organic additives in the electroplating solution by combining with free radicals in the electroplating solution, thereby reducing the number of free radicals combining with organic additives. Embodiments of the present invention may include antioxidants such as sodium stannate, hydroquinone, or butylatedhydroxytoluene (BHT) in a concentration sufficient to reduce the degradation of organics, for example, from about 500 ppm to about 5000 ppm.

As a result of the reduction in organic additive degradation within the electroplating solution, plating solutions including an anti-oxidant may not require organic additive replenishment to maintain plating performance. In one embodiment of the invention, after an extended period of use, the electroplating solution is replaced. Although the organic additives may still degrade over time, the degradation of organics will be reduced as will the effect of organic build-up on plating. Therefore, the life of the electroplating solution is extended, for example, the life of the electroplating solution may be doubled. As a result, total replacement of the electroplating solution is a viable alternative to costly and imprecise chemical analysis and electroplating solution replenishment systems. The plating solution may be replaced at any point in the plating process where it is economically viable to do so. Embodiments of the invention contemplate replacing the solution when the effective additive concentration reaches a certain level, such as the point where the additive degradation is equal to the degradation of organic additives in a conventional system when the conventional system's plating solution is dumped.

The present invention will be further illustrated with reference to the following examples, which aid in the understanding of the present invention, but which are not to be construed as limitations thereof.

### EXAMPLE 1

### Degradation Rates for Organic Additives in a Conventional Plating Solution

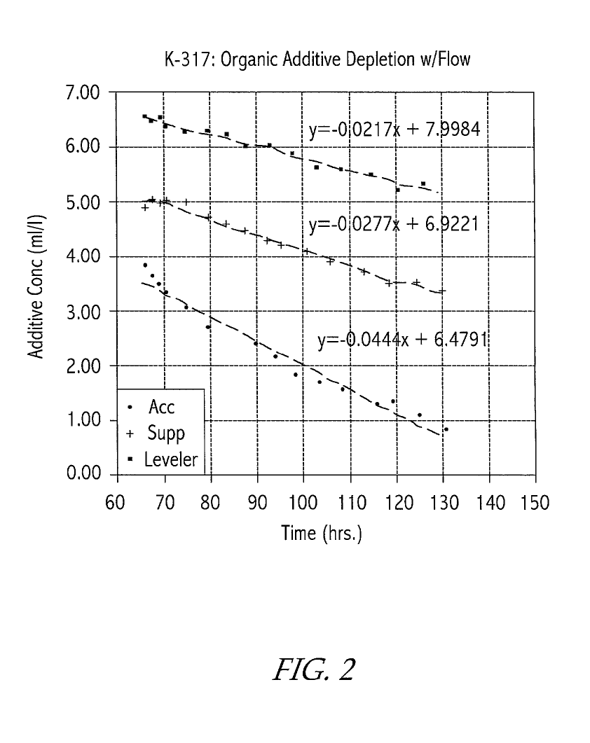

A substrate was plated in an electroplating solution initially consisting of 50 g/L of copper, 30 g/L of sulfuric acid, 50 ppm of chloride ion, 6.48 mL/L of leveler, 5.92 mL/L of suppressor, and 8 mL/L of accelerator. The organic additive concentrations were measured using CVS analysis to determine the rate of organic additive degradation in the electroplating solution over time. FIG. 2 illustrates the organic additive concentration throughout the plating process. The results show that over a period of 130 hours, the rate of accelerator degradation was 0.022 mL/(L*hr), the rate of suppressor degradation was 0.028 mL/(L*hr), and the rate of leveler degradation was 0.044 mL/(L*hr).

### EXAMPLE II

### Representative Example of Degradation Rates for Organic Additives in a Plating Solution Including Sodium Stannate

A substrate is plated in a solution containing 500 ppm of sodium stannate added to the initial electroplating solution of Example I. Over a period of 130 hours, the rate of accelerator degradation is expected to be less than 0.022 mL/(L*hr); likely the rate will be less than 0.011 mL/(L*hr). The rate of suppressor degradation is expected to be less than 0.028 mL/(L*hr); likely the rate will be less than 0.014 mL/(L*hr). The rate of leveler degradation is expected to be less than 0.044 mL/(L*hr); likely the rate will be less than 0.022 mL/(L*hr).

While the foregoing is directed to embodiments of the present invention, other and further embodiments of the invention may be devised without departing from the basic scope thereof, and the scope thereof is determined by the claims that follow.

What is claimed is:

1. A method for plating copper on a substrate, comprising adding an anti-oxidant to a plating solution in an amount effective to reduce degradation of organic additives in the plating solution, the anti-oxidant being selected from the group consisting essentially of sodium stannate, hydroquinone, butylated hydroxy toluene, and combinations thereof.

2. The method of claim 1, wherein a concentration of the anti-oxidant is between about 500 ppm and about 5000 ppm.

3. The method of claim 2, wherein the plating solution is configured to support copper plating.

4. The method of claim 2, wherein the plating solution includes copper ions in a concentration of between about 5 g/L and about 100 g/L.

5. The method of claim 2, wherein the plating solution includes an acid in a concentration of between about 5 g/L and about 200 g/L.

6. The method of claim 2, wherein the plating solution includes chloride ions in a concentration of between about 10 ppm and about 200 ppm.

7. The method of claim 1, wherein the amount of anti-oxidant added into the plating solution per unit time is calculated to correspond to an amount of organic additives degrading in the plating solution per unit time.

8. The method of claim 1, wherein the plating solution comprises:
copper ions at a concentration of between about 5 g/L and about 100 g/L;
an acid at a concentration of between about 5 g/L and about 200 g/L; chloride ions at a concentration of between about 10 ppm and about 200 ppm;
sodium stannate at a concentration of between about 500 ppm and about 5000 ppm; and
at least one organic plating additive configured to enhance a plating characteristic of the metal on the substrate.

9. The method of claim 8, wherein the at least one organic plating additive comprises at least one of a leveler, a suppressor, and an accelerator.

10. The method of claim 1, further comprising:
disposing of the entire plating solution after a period of time; and
replacing the plating solution.

11. A method for plating metal on a substrate, comprising:
disposing the substrate and an anode in a plating solution, the plating solution comprising:
metal ions;
one or more organic additives configured to enhance one or more plating characteristics; and
at least one anti-oxidant in an amount effective to reduce degradation of the one or more organic additives; and
plating metal ions from the plating solution onto the substrate.

12. The method of claim 11, further comprising:
disposing of the entire plating solution after a period of time; and
replacing the plating solution.

13. The method of claim 11, wherein the metal ions comprise copper.

14. The method of claim 11, wherein the metal ions comprise copper in a concentration between about 5 g/L and about 100 g/L.

15. The method of claim 11, wherein the at least one anti-oxidant is selected from the group consisting essentially of sodium stannate, hydroquinone, and butylated hydroxy toluene.

16. The method of claim 11, wherein the anti-oxidant is sodium stannate at a concentration of between about 500 ppm and about 5000 ppm.

17. The method of claim 16, wherein the plating solution further comprises chloride ions at a concentration of between about 10 ppm and about 200 ppm.

18. The method of claim 16, wherein the plating solution further comprises an acid at a concentration of between about 5 g/L and about 500 g/L.

19. The method of claim 11, wherein the plating solution comprises:
copper ions at a concentration of between about 5 g/L and about 100 g/L;
an acid at a concentration of between about 5 g/L and about 200 g/L;
chloride ions at a concentration of between about 10 ppm and about 200 ppm; and
sodium stannate at a concentration of between about 500 ppm and about 5000 ppm.

20. A plating solution for an electrochemical plating system, comprising:
a liquid solution containing copper ions to be plated on a substrate;
at least one organic plating additive configured to facilitate a plating characteristic of the copper ions onto a substrate; and
at least one anti-oxidant in an amount sufficient to reduce the degradation of the at least one organic plating additive in the plating solution.

21. The plating solution of claim 20, wherein the liquid solution comprises copper sulfate.

22. The plating solution of claim 20, wherein the copper ions are at a concentration of between about 5 g/L and about 100 g/L.

23. The plating solution of claim 22, further comprising an acid at a concentration of between about 5 g/L and about 200 g/L.

24. The plating solution of claim 22, further comprising chloride ions at a concentration of between about 10 ppm and about 200 ppm.

25. The plating solution of claim 20, wherein the at least one anti-oxidant is selected from the group consisting essentially of sodium stannate, hydroquinone, and butylated hydroxy toluene.

26. The plating solution of claim 22, wherein the anti-oxidant is sodium stannate at a concentration of between about 500 ppm and about 5000 ppm.

27. The plating solution of claim 20, further comprising;
copper ions at a concentration of between about 5 g/L and about 100 g/L;
an acid solution at a concentration of between about 5 g/L and about 200 g/L;
chloride ions at a concentration of between about 10 ppm and about 200 ppm; and
sodium stannate at a concentration of between about 500 ppm and about 5000 ppm.

28. The plating solution of claim 20, wherein the at least one organic plating additive comprises at least one of a suppressor, leveler, and an accelerator.

29. A method for reducing degraded organic plating additives in an electrochemical plating solution, comprising adding sodium stannate to the electrochemical plating solution, the sodium stannate being added in an amount corresponding to a time varying amount of degraded organic plating additives generated in the electrochemical plating solution.

30. The method of claim 29, wherein a concentration of the sodium stannate is between about 500 ppm and about 5000 ppm.

31. The method of claim 29, wherein the electrochemical plating solution is configured to plate copper.

32. The method of claim 31, wherein the electrochemical plating solution includes copper ions in a concentration of between about 5 g/L and about 100 g/L.

33. The method of claim 31, wherein the electrochemical plating solution includes an acid in a concentration of between about 5 g/L and about 200 g/L.

34. The method of claim 31, wherein the plating solution includes chloride ions in a concentration of between about 10 ppm and about 200 ppm.

35. A method for plating copper in an electrochemical plating system, comprising contacting a substrate having an electrical bias applied thereto with a plating solution, wherein the plating solution comprises a copper source, at least one organic additive, and at least one anti-oxidant selected from the group consisting of sodium stannate, hydroquinone, butylated hydroxy toluene, and combinations thereof.

36. The method of claim 35, wherein a concentration of the sodium stannate is between about 500 ppm and about 5000 ppm.

37. The method of claim 36, wherein the plating solution includes copper ions supplied by a copper sulfate solution, wherein the copper ions are in a concentration of between about 5 g/L and about 100 g/L.

38. The method of claim 36, wherein the plating solution includes an acid in a concentration of between about 5 g/L and about 200 g/L.

39. The method of claim 36, wherein the plating solution includes chloride ions in a concentration of between about 10 ppm and about 200 ppm.

40. The method of claim 36, wherein the amount of anti-oxidant added into the plating solution per unit time is calculated to correspond to an amount of organic additives degrading in the plating solution per unit time.
